(19) United States
(12) Patent Application Publication
(10) Pub. No.: US 2005/0130329 A1
(43) Pub. Date: Jun. 16, 2005

(54) Method for the prediction of the source of semiconductor part deviations

(76) Inventors: Yushan Liao, Xindian City (TW); Chi-Kun Yu, Taoyuan (TW); Wen-Pin Lu, Jung-Li City (TW); Chun-Ching Hsieh, Taipei City (TW)

Correspondence Address: DUANE MORRIS, LLP;IP DEPARTMENT, ONE LIBERTY PLACE, PHILADELPHIA, PA, 19103-7396, US

(21) Appl. No.: 10/737,550

(22) Filed: Dec. 16, 2003

(51) Int. Cl. H01L 21/00

(52) U.S. Cl. 438/5

(57) ABSTRACT

A method for predicting a source of semiconductor part deviation is disclosed. The method includes the steps of selecting at least one chart including part parameters and associating with each of the part parameters at least one fabrication process, which are stored in recipes, scanning the selected charts for deviations in the part parameters, wherein the deviations are determined by monitoring a trend of recent values of the part parameters, indicating the charts containing the part parameters wherein the part parameter values are determined as being outside of at least one trend tolerance value associated with the parameter, identifying, in each of the indicated charts at least one process associated with each of the part parameter deviations outside the at least one tread tolerance value, and determining a source of the parameter deviation by correlating each of the identified at least one processes. In one aspect of the invention, the selected chart includes the relationship between part parameters and processes.

### BACKGROUND OF THE INVENTION

1. Field of the Invention

This invention relates generally to semiconductor manufacturing, and, more particularly, to a method for predicting or determining the source of part deviations.

2. Description Of The Related Art

With the advances in the semiconductor industry, manufacturers have been able to continue advances in circuit miniaturization in which the density of circuits doubles every year or two. Known as “Moore's Law,” it was predicted in 1965. that the number of transistors on a computer chip would double every year or two. Although Moore's Law has maintained relevance over the year, the pathway to the success of the semiconductor industry has been one that is forged through hard work and advances in research.

In the manufacture of semiconductor parts, these advances have required that the processes by which the devices have been manufactured change and adapt to the sensitivities of a new generation of semiconductor devices in which manufacturing processes have become more complex and the tolerances afforded have shrunk. The net result is that as circuit density increases the margin for error, or deviation from nominal, decreases.

One area of semiconductor manufacturing that has been affected by these changes is in the ability of engineers to predict or determine when minor changes in the manufacturing process will result in deviations in the parts that will render the parts defective and unusable. Today, engineers accomplish many of these tasks that direct the manufacturing or fabrication of partS in a combination of steps and materials that are referred to as recipes. However, the engineers do not necessarily coordinate all of their tasks as the tasks may be handled independently and in many instances manually. Thus, there is no standard procedure to determine when a deviation in the fabrication of the part will cause a part to be considered defective and unusable. There is also no adequate way to determine or predict which process or processes caused the deviation to occur. Presently, the task of determining part deviations resides in the largely manual process of checking part recipes and production reports, referred to as statistical process control (SPC) charts, to determine the cause of the part deviation. Thus, there is a need for a method to predict the source of part deviations.

### SUMMARY OF THE INVENTION

A method for predicting a source of semiconductor part deviation is disclosed. The method includes the steps of selecting at least one chart including part parameters and associating with each of the part parameters at least one fabrication process, which are stored in recipes, scanning the selected charts for deviations in the parts parameters wherein the deviations are determined by monitoring a trend of recent values of the part parameters, indicating the charts containing the part parameters wherein the part parameter values are determined as being outside of at least one trend tolerance value associated with the parameter, identifying, in each of the indicated charts at least one process associated with each of the part parameter deviations outside the at least one tread tolerance value, and determining a source of the parameter deviation by correlating each of the identified at least one processes. In one aspect of the invention, the selected chart includes the relationship between part parameters and processes.

### BRIEF DESCRIPTION OF THE DRAWINGS

Other aspects, advantages and novel features of the invention will become more apparent from the following detailed description of the invention when considered in conjunction with the accompanying drawings wherein:

FIG. 1 is a block diagram of a process flow for predicting part deviations in accordance with the principles of the invention;

FIG. 2 is a chart representative of the relationship between part characteristics and processes;

FIG. 3 illustrates a flowchart for determining part deviation;

FIG. 4 illustrates a flowchart for reviewing manufacturing operations;

FIG. 5 illustrates a flowchart for identifying manufacturing process and part deviation; and

FIG. 6 illustrates a flow chart for evaluating results of manufacturing processes in accordance with the principles of the present invention.

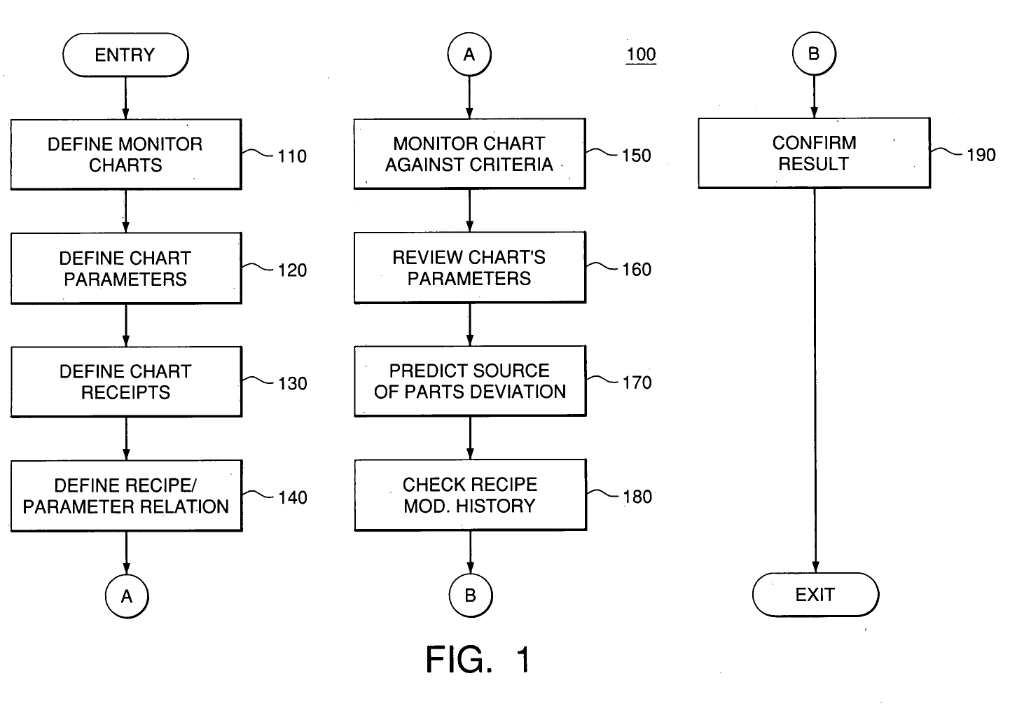

It is to be understood that these drawings are solely for purposes of illustrating the concepts of the invention and are not intended as a definition of the limits of the invention. The embodiments shown in FIGS. 1-6 and described in the accompanying detailed description are to be used as illustrative embodiments and should not be construed as the only manner of practicing the invention. Also, the same reference numerals, possibly supplemented with reference characters where appropriate, have been used to identify similar elements.

### DETAILED DESCRIPTION

FIG. 1 illustrates a process 100 incorporating a set of procedures that enables a user to predict the source of deviation of parts by checking the part recipes and SPC charts. The method unifies the way in which users can monitor and track production parameters in a way that allows for automated monitoring.

At block 110, a user selects one or more charts from a plurality of charts to be examined. At block 120, a user defines a number of chart parameters and associated known tolerance values. Conventionally, these tolerance values are determined from previous experience of prior production processes of the same or substantially similar parts. At block 130, a user defines the selected chart's recipes. At block 140, a user defines the project steps in which the selected charts, selected recipes and selected parameters are combined for use in a production run. The relation between chart, recipe and parameter may also be amended to meet desired user or customer criteria. At block 150, the production process is monitored with regard to the selected charts and parameters. At block 160, a user may review selected chart parameters with regard to the production process. At block 170, a user may review the number and type of part deviations and associated process steps that contribute to the part deviation in order to identify the source of the part deviation. At block 180, a user is able to review the process recipes. And, at block 190, a user is able to confirm the results of the manufacturing process.

It will be recognized by those skilled in the art that the processing shown in blocks 110-150 may be performed before each step in the manufacture of a specific product or product lot. In another aspect of the invention, the operations of block 110-140 may be predetermined and repeated between different product runs or product lot runs. Hence, a database of chart, parameter and recipe definitions may be developed and relied upon for future production runs. The operations of blocks 150-190 are representative of tasks performed by a monitoring system based upon the inputs provided by blocks 110-140. Thus, future production runs may, for example, begin from block 150 or may only require some of the steps described in steps 110-140.

A more detailed explanation of each of the process steps is set forth as follows. At block 110, a user or engineer defines one or more charts that need to be monitored. A list of charts is provided or made available from which engineers may select one or more desired charts associated with the current production run for the desired part. The charts may be pre-determined and stored in a Manufacturing Execution System (MES). MES programs are well known in the art. For example, PROMIS is a commercial software MES program that combines planning, costing, document control, SPC, production and performance management in one comprehensive package. PROMIS is a registered trademark of Brooks Automation, Inc., Chelmsford, Mass., 01824

From the provided list of charts, a user may select one or more charts suitable for the current operation or production run. The selected charts are referred to hereinafter as the monitored charts. The monitored charts may then be stored in a database for subsequent operation. The database may be a commercial database, such as ORACLE, or a self-developed or home-grown database. In a preferred embodiment, a commercial database is selected.

At block 120, the user is provided with a list of production parameters to select part parameters that relate to the “monitored charts.” Parameters may be selected from, but not limited to, the group consisting of thickness, uniformity of thickness, sputter rate, uniformity of sputter rate, deposition/sputter (D/S), uniformity of D/S, Refractive Index (RI), and stress. The user may pick or select one or more of these part parameters for each selected chart. Following the selection of the part parameters, the part parameters are stored in relation to the monitored chart for which they were selected.

At block 130, the user may select recipes associated with each monitored chart for fabricating the part or parts. The user may be provided with a list of known fabrication recipes for review. The user may select one or more of the recipes for each monitored chart. It will be appreciated that more complex parts may require a greater combination of recipes. Once the recipes have been selected they are stored in the database.

Recipes are preferably stored in one or more databases, conventionally referred to as recipe databases. In some aspects, recipe databases may be commercial software databases that include information that is proprietary to the manufacturer or foundry. It will be appreciated by those skilled in the art that any recipe database may be easily adapted for use with the presently described invention. Recipes associated with methods for fabrication of integrated circuits are known in the art. In some cases, the recipes may be held as trade secrets that provide a commercial advantage to the owner of the recipe. Details of individual recipes are not discussed further herein as individual recipes are not relevant to the invention disclosed.

At block 140, a user may define the recipe's steps and parts parameters as they relate to each of the monitored charts. Thus the user may tailor the production process for the part or parts to be made. As each recipe may contribute some element of the process step, one skilled in the art would appreciate that a processing step may require one or more recipes to complete the desired process step.

At block 150, the user defines the monitoring criteria for each of the monitored charts. In this case, the user is provided with a list of predetermined rules from which monitoring parts parameters may be checked and validated. The rules may be determined in part on the tolerance values desired, other parameters of the part and the history of generating the desired part.

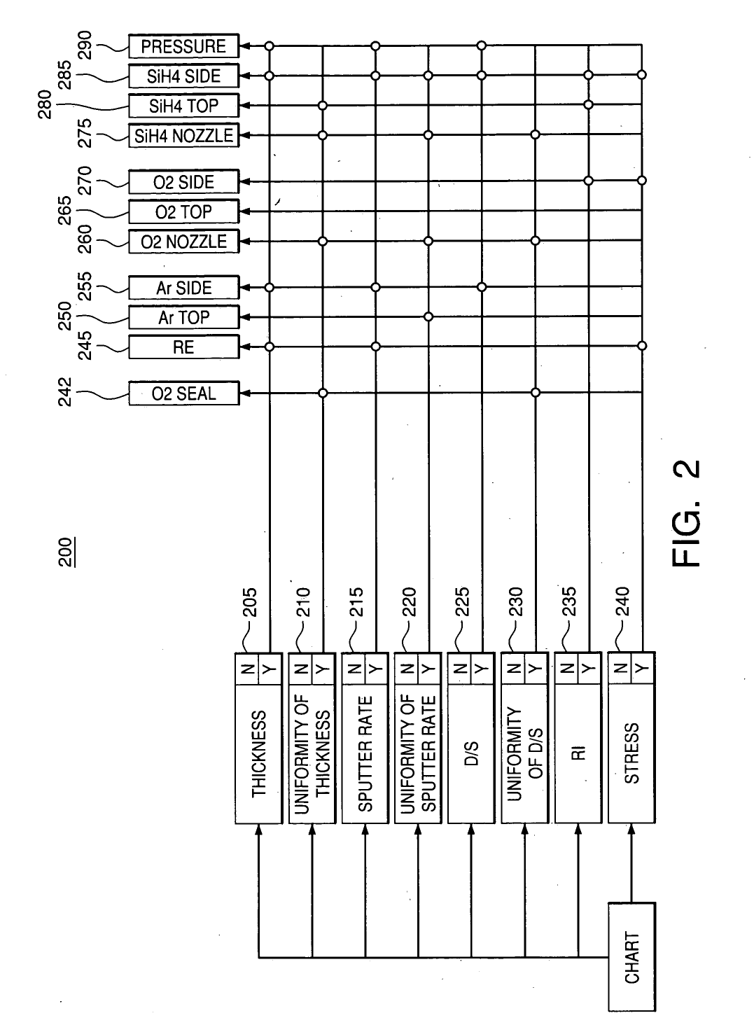

FIG. 2 illustrates an exemplary relation, similar to that used in block 150 of FIG. 1, between parameters and processes to determine the process or processes that may contribute to part deviation. In this exemplary parameter/process relation, parameters may be selected from a group of part parameters such as thickness 205, uniformity of thickness 210, sputter rate 215, dispersion/sputter (D/S) 225, uniformity of D/S 230, RI 235 and stress 240, while processes that may contribute to deviations in the parts parameters may, for example, be selected from, but not limited to, the group consisting of Oxygen (O₂) seal 240, RF 245, Ar-top 250, O₂ nozzle 260, O₂ top 265, O₂ side 270, SiH₄-nozzle 275, SiH₄ top 280, SiH₄ side 285 and pressure 290. Thus, for the exemplary relation shown, deviation of a part thickness may be caused by errors in either RF process 245, Ar-side process 255, SiH₄ side process 285, or pressure 290 and combinations thereof. Similarly, deviation in part parameter D/S 225 may be caused by errors in one or more of Ar-side process 255, SiH₄-side 285 and/or pressure 290.

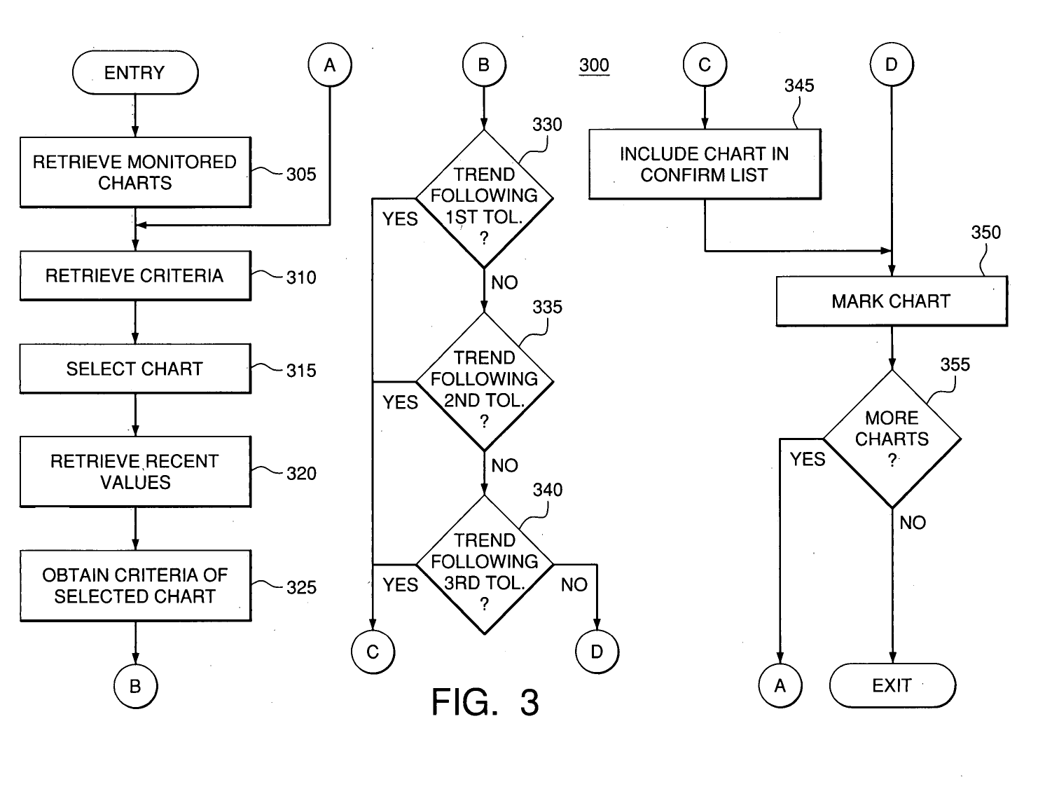

FIG. 3 illustrates a flow chart for an exemplary process 300 for reviewing chart parameters identified in block 160 of FIG. 1. In the illustrative process 300, the selected monitored charts are retrieved at block 305. At block 310, criteria associated with the selected monitored charts are obtained. At block 315, one of the monitored charts is selected. At block 320, a recent value associated with the parameters of the selected chart is obtained. At block 325, the criteria, i.e., trend tolerance values, associated with the parameters in the selected chart are obtained. In this illustrated case, three trend tolerance values are selected. At block 330, a determination is made whether the recent value of the parameter is within the first of the associated trend tolerance values. If the answer is in the affirmative, then processing continues at block 345.

However, if the answer is negative, then a determination is made whether the recent value is within the second of the associated trend tolerance values. If the answer is in the affirmative, then processing continues at block 345.

However, if the answer is negative, then a determination is made whether the recent parameter value is within the third of the associated trend tolerance values. If the answer is in the affirmative, then processing continues at block 345. However, if the answer is in the negative, then the selected chart is marked to preclude its subsequent use.

At block 345 the selected chart is included in a list of charts wherein the monitored parameters are within at least one tolerance value. In a preferred embodiment, the trend tolerance values are selected to be 3, 5 and 10 units of a measure of the part parameter tested. In this preferred embodiment, the trend of the deviation is compared to the tolerances established.

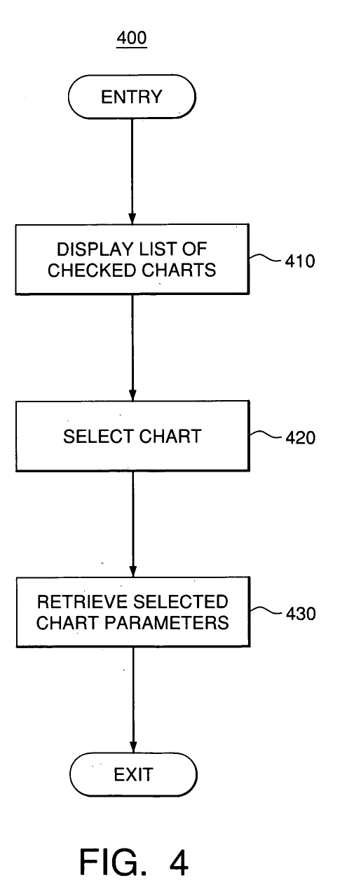

FIG. 4 illustrates a flow chart for an exemplary process 400 for selecting charts marked at block 345 of FIG. 3. In this exemplary process 400, a list of checked charts is displayed at block 410. At block 420, one of the displayed charts is selected. At block 430, the parameters associated with the selected chart are obtained. As previously discussed, the parameters associated with a chart are stored in a database.

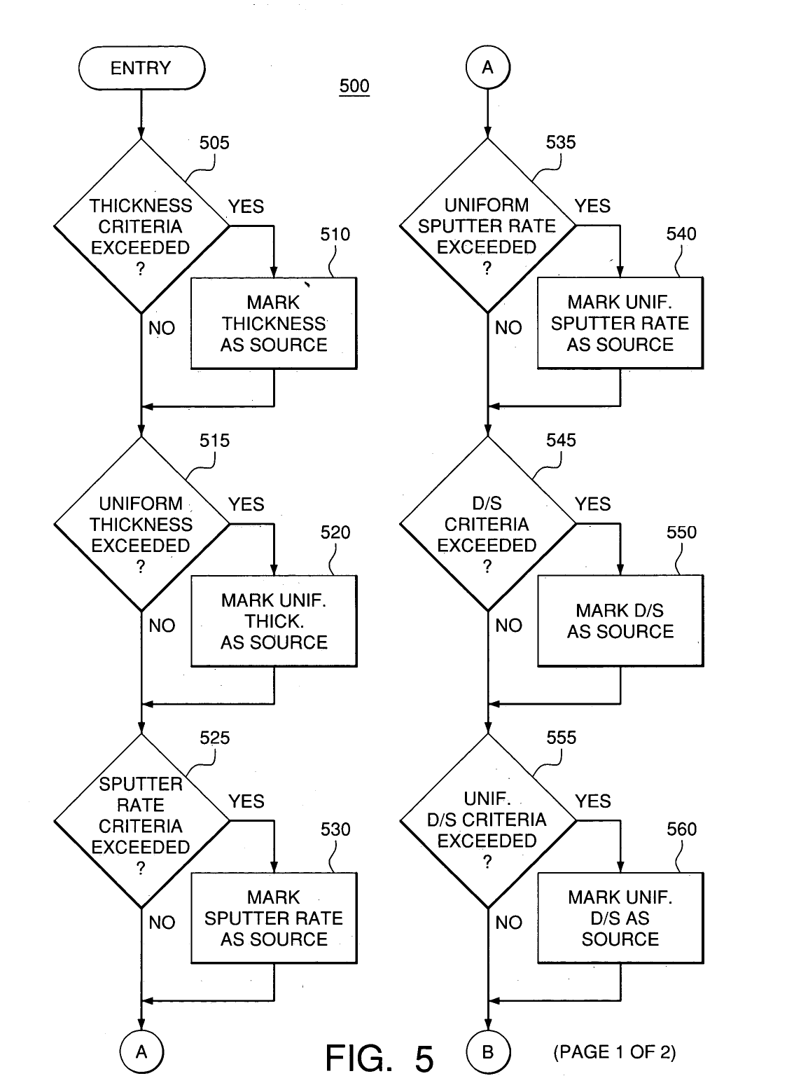

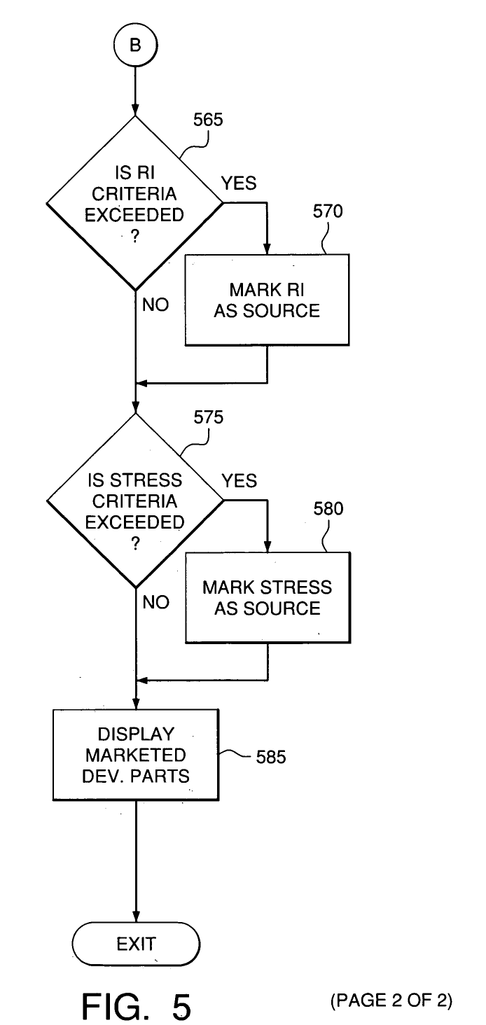

FIG. 5 illustrates a flow chart of a process 500 for associating parameters with processes contributing to part deviation in accordance with the principles of the invention. In this exemplary process, at block 505 a determination is made whether the tolerances associated with the thickness parameters have been exceeded. If the answer is in the affirmative, then the processes associated with thickness parameters are marked at block 510. At block 515 a determination is made whether the tolerance associated with the uniformity of thickness parameters has been exceeded. If the answer is in the affirmative, then the processes associated with uniformity of thickness parameters are marked at block 520. At block 525 a determination is made whether the tolerance associated with the sputter rate parameters has been exceeded. If the answer is in the affirmative, then the processes associated with sputter rate parameters are marked at block 530. At block 535 a determination is made whether the tolerance associated with the uniformity of sputter rate parameters has been exceeded. If the answer is in the affirmative, then the processes associated with uniformity of sputter rate parameters are marked at block 540. At block 545 a determination is made whether the tolerance associated with the D/S parameters have been exceeded. If the answer is in the affirmative, then the processes associated with D/S parameters are marked at block 550. At block 555 a determination is made whether the tolerance associated with the uniformity of D/S parameters has been exceeded. If the answer is in the affirmative, then the processes associated with uniformity of D/S parameters are marked at block 560. At block 565 a determination is made whether the tolerance associated with the RI parameters has been exceeded. If the answer is in the affirmative, then the processes associated with RI parameters are marked at block 570. At block 575 a determination is made whether the tolerance associated with the stress parameters has been exceeded. If the answer is in the affirmative, then the processes associated with stress parameters are marked at block 580. At block 585, a display of each of the marked processes is made available to the user. In one aspect of the invention the display may include a histogram of processes to determine the process common to the deviation part.

Although FIG. 5 illustrates a process wherein each of the exemplary part parameters is tested for deviations, it would be well within the skill of those in the art to develop a similar process using fewer or more part parameter tests or to devise means not to perform certain tests when a particular parameter is not selected. Such aspects of the invention, although not shown, are contemplated to be within the scope of the invention.

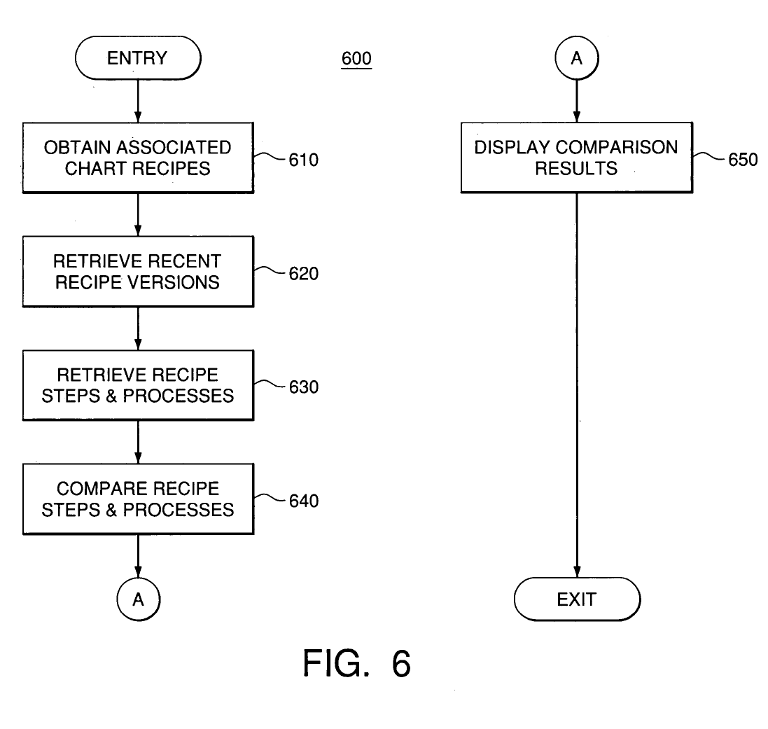

FIG. 6 illustrates a flow chart of a process 600 for reviewing the processes associated with reviewing and predicting deviation parts, as shown at block 170 of FIG. 1. In this exemplary process, recipes associated with the selected chart are obtained at block 610. At block 620, versions of the selected recipes are obtained. At block 630 the steps and processes associated with each of the retrieved recipes are obtained. At block 640, the steps and processes of the retrieved recipes are compared for differences. At block 650, the results of the comparison are made available to the user.

Although the invention has been described in terms of exemplary embodiments, it is not limited thereto. For example, although the present invention has been described with regard to a fixed number of parameters, it would be recognized by those skilled the art that the invention may be applied to less than or more than the parameters discussed herein. Similarly, the present invention may be used with one or more of the trend rules discussed herein.

Accordingly, the appended claims should be construed broadly, to include other variants and embodiments of the invention, which may be made by those skilled in the art without departing from the scope and range of equivalents of the invention.

1. A method for predicting the source of semiconductor part deviation comprising the steps of:
selecting at least one chart, each including part parameters and associating with each of said part parameters at least one process, which is stored in recipes;
scanning said selected charts for deviations in said part parameters, wherein said deviations are determined by monitoring a trend of recent values of said part parameters;
indicating said charts containing said part parameters wherein said part parameter values are determined as being outside of at least one trend tolerance value associated with said parameter;
identifying, in each of said indicated charts at least one process associated with each of said part parameter deviations outside said at least one trend tolerance value; and
determining a source of said parameter deviations by correlating each of said identified at least one processes.

2. The method as recited in claim 1, wherein said part parameters are selected from the group consisting of: thickness, uniformity of thickness, sputter rate, uniformity of sputter rate, D/S, uniformity of D/S, RI, stress.

3. The method as recited in claim 1, wherein said processes are selected from the group consisting of: Oxygen seal, Rf, Ar top, Ar side, Oxygen nozzle, Oxygen top, Oxygen side, SiH₄ nozzle, SiH₄, top, SiH₄ side, pressure.

4. The method as recited in claim 1, wherein associating part parameters with at least one process is predetermined.

5. The method as recited in claim 1, wherein associating part parameters with at least one process is performed manually.

6. The method as recited in claim 1, wherein information regarding associating part parameters with at least one process is included in said chart.

7. The method as recited in claim 1, further comprising the step of:
storing said part parameter recent values; and
storing said associated recipes.

8. The method as recited in claim 1, further comprising the step of:
viewing said part parameters.

9. The method as recited in claim 1, further comprising the step of:
viewing said recipes.

10. A method for predicting the source of semiconductor part deviation comprising the steps of:
selecting at least one chart, each including part parameters and associating with each of said part parameters at least one process, which is stored in recipes;
scanning said selected charts for deviations in said part parameters, wherein said deviations are determined by monitoring a trend of recent values of said part parameters;
indicating said charts containing said part parameters wherein said part parameter values are determined as being outside of at least one trend tolerance value associated with said parameter;
identifying, in each of said indicated charts, a process of said at least one process responsible for each of said part parameter deviations to be outside said at least one trend tolerance value; and
determining a source of said parameter deviations by correlating each of said identified at least one processes.

11. A method for predicting the source of semiconductor part deviation comprising the steps of:
selecting a plurality of charts, each including part parameters and associating with each of said part parameters at least one process, which is stored in recipes;
scanning each of said charts for deviations in said part parameters, wherein said deviations are determined by monitoring a trend of recent values of said part parameters;
indicating said charts containing said part parameters wherein said part parameter values are determined as being outside of at least one trend tolerance value associated with said parameter;
identifying, in each of said indicated charts, which process of said at least one process was the cause of each of said part parameter deviations to be outside said at least one trend tolerance value; and
determining a source of said parameter deviations by correlating each of said identified at least one processes.
